(19) United States
(12) Patent Application Publication
(10) Pub. No.: US 2026/0363106 A1
(43) Pub. Date: Nov. 12, 2026

(54) I/O INTERFACE INCLUDING REPAIR LANE

(71) Applicant: ELECTRONICS AND TELECOMMUNICATIONS RESEARCH INSTITUTE, Daejeon (KR)

(72) Inventors: Yi Gyeong KIM, Daejeon (KR); Young Deuk JEON, Sejong-si (KR); Min Hyung CHO, Daejeon (KR); Min Seok CHOI, Daejeon (KR); Jin Ho HAN, Seoul (KR)

(21) Appl. No.: 19/664,016

(22) Filed: Apr. 30, 2026

(30) Foreign Application Priority Data
May 8, 2025 (KR) 10-2025-0059807
Aug. 21, 2025 (KR) 10-2025-0116518

(51) Int. Cl. H10W 70/62; H10W 42/20; H10W 70/60

(52) U.S. Cl. CPC H10W 70/641; H10W 42/261; H10W 70/611

(57) ABSTRACT

I/O interface including repair lane. Provided is a semiconductor package including: a first chiplet including a transmission interface; a second chiplet including a reception interface; and a plurality of interconnects configured to connect the first chiplet to the second chiplet, wherein an interposer on which the plurality of interconnects are disposed further includes a plurality of shield wirings, the plurality of interconnects include a plurality of data lanes, a plurality of strobe lanes, and a plurality of repair lanes, the plurality of data lanes transmit or receive at least one of a data signal and a differential signal, the plurality of strobe lanes transmit or receive a differential signal, and the plurality of repair lanes transmit or receive a data signal, and the differential signal includes at least one of a strobe signal and a clock signal.

### CROSS-REFERENCE TO RELATED APPLICATIONS

This application claims the benefit of and priority to Korean Patent Application No. 10-2025-0059807, filed on May 8, 2025, and Korean Patent Application No. 10-2025-0116518, filed on Aug. 21, 2025, the entire disclosures of which are incorporated by reference herein in their entirety.

### BACKGROUND

### Field of the Invention

The present disclosure relates to an input/output interface including a repair lane.

### 2. Description of Related Art

The contents to be described below merely provide background information related to the present embodiments and do not constitute the related art.

A high-performance integrated circuit (IC) is manufactured by integrating a plurality of chiplets in a packaging process so that the plurality of chiplets operate as a single semiconductor using high-density bumps and interconnects. In the chiplet semiconductor in which the plurality of chiplets are integrated, defects may occur in the interconnects during a manufacturing process. In order to resolve the defects occurring in the interconnects, an input/output interface responsible for data communication between the chiplets is required to have a lane repair function. However, even in an existing input/output interface including a lane repair function, there is a problem in that, when a defect occurs in an interconnect for a strobe lane, the entire interconnect becomes unusable.

### SUMMARY

An object of the present disclosure is to provide a semiconductor chiplet capable of transmitting or receiving signals using a repair lane when a defect occurs in an interconnect of a lane for transmitting or receiving data signals and differential signals.

The problems to be solved by the present invention are not limited to those mentioned above, and other problems that are not mentioned will be clearly understood by those skilled in the art from the following description.

According to at least one embodiment, the present disclosure provides a semiconductor package comprising: a first chiplet including a transmission interface; a second chiplet including a reception interface; and a plurality of interconnects configured to connect the first chiplet to the second chiplet, wherein an interposer on which the plurality of interconnects are disposed further includes a plurality of shield wirings, the plurality of interconnects include a plurality of data lanes, a plurality of strobe lanes, and a plurality of repair lanes, the plurality of data lanes transmit or receive at least one of a data signal and a differential signal, the plurality of strobe lanes transmit or receive a differential signal, and the plurality of repair lanes transmit or receive a data signal, and the differential signal includes at least one of a strobe signal and a clock signal.

According to another embodiment, the present disclosure provides a chiplet comprising: a transmission interface configured to transmit signals using a first plurality of interconnects; and a reception interface configured to receive signals using a second plurality of interconnects, wherein each of the first plurality of interconnects and the second plurality of interconnects includes a data lane, a strobe lane, and a repair lane, each interposer on which the first plurality of interconnects and the second plurality of interconnects are disposed further includes a shield wiring, the shield wiring includes a plurality of shield wirings, the data lane includes a plurality of data lanes to transmit or receive at least one of a data signal and a differential signal, the strobe lane includes a plurality of strobe lanes to transmit or receive a differential signal, the repair lane includes a plurality of repair lanes to transmit or receive a data signal, and the differential signal includes at least one of a strobe signal and a clock signal.

According to an embodiment of the present disclosure, there is an advantage in that, when a defect occurs in an interconnect including a data lane for transmitting or receiving data signals, the data signals can be transmitted or received without interruption by using a repair lane as a data lane.

According to an embodiment of the present disclosure, there is an advantage in that, when a defect occurs in an interconnect including a strobe lane for transmitting or receiving a strobe signal and a clock signal, it is possible to transmit or receive the strobe signal and the clock signal while maintaining characteristics of the strobe signal by using a repair lane.

The effects of the present disclosure are not limited to those mentioned above, and other effects that are not mentioned will be clearly understood by those skilled in the art from the following description.

### BRIEF DESCRIPTION OF THE DRAWINGS

FIG. 1 is a diagram schematically illustrating an input/output interface including a repair lane according to an embodiment of the present disclosure.

FIG. 2 is a diagram illustrating an operation of an input/output interface including a repair lane when there is a defect in an interconnect including a data lane according to an embodiment of the present disclosure.

FIG. 3 is a diagram illustrating an operation of the input/output interface including a repair lane when there is a defect in an interconnect including a strobe lane according to an embodiment of the present disclosure.

FIG. 4 is a diagram illustrating a transceiver interface including a repair lane according to an embodiment of the present disclosure.

### DETAILED DESCRIPTION OF THE INVENTION

Hereinafter, some exemplary embodiments of the present disclosure will be described in detail with reference to the accompanying drawings. In the following description, like reference numerals preferably designate like elements, although the elements are shown in different drawings. Further, in the following description of some embodiments, a detailed description of known functions and configurations incorporated therein will be omitted for the purpose of clarity and for brevity.

Additionally, various terms such as first, second, A, B, (a), (b), etc., are used solely to differentiate one component from the other but not to imply or suggest the substances, order, or sequence of the components. Throughout this specification, when a part ‘includes’ or ‘comprises’ a component, the part is meant to further include other components, not to exclude thereof unless specifically stated to the contrary. The terms such as ‘unit’, ‘module’, and the like refer to one or more units for processing at least one function or operation, which may be implemented by hardware, software, or a combination thereof.

The following detailed description, together with the accompanying drawings, is intended to describe exemplary embodiments of the present disclosure and is not intended to represent the only embodiments in which the present disclosure may be practiced.

A repair lane in a semiconductor chiplet refers to a redundancy lane provided to replace an existing lane in which a failure has occurred among data lanes or strobe lanes used for communication between semiconductor chiplets.

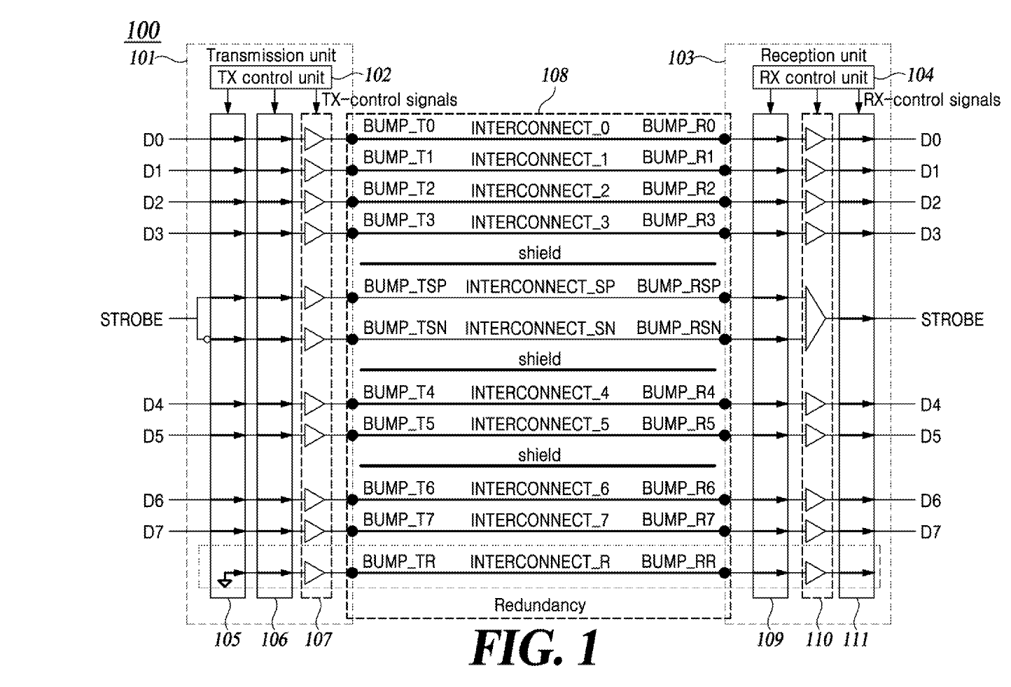

FIG. 1 is a diagram schematically illustrating an input/output interface including a repair lane according to an embodiment of the present disclosure.

An input/output interface 100 including a repair lane may include all or some of a transmission unit 101, a reception unit 103, a plurality of interconnects 108, a shield wiring (shield), and a communication unit (not shown). Not all components illustrated in FIG. 1 are essential components, and some components may be modified or omitted, or other components may be added.

Components of the input/output interface 100 including a repair lane may exchange signals with each other using the communication unit. The signals may include data. For example, the signals may be electrical signals or optical signals, but are not limited thereto.

The communication unit may transfer a signal for synchronizing mapping information between a TX control unit 102 and an RX control unit 104 in order to perform lane mapping. The signal for synchronizing the mapping information may be transferred to synchronize the TX control unit 102 and the RX control unit 104. Here, the mapping information refers to information defining whether a defect has occurred in each lane, a position at which the defect has occurred, and connection relationships between data lanes and strobe lanes.

The transmission unit 101 may include all or some of a TX single signal path selection unit 105, a TX differential signal path selection unit 106, the TX control unit 102, and a transmission circuit 107. The transmission unit 101 transmits data of a chiplet to another chiplet.

Each of the TX single signal path selection unit 105 and the TX differential signal path selection unit 106 selects (maps) an electrical connection path between data transferred from a chiplet including a transmission interface and an input/output path. Here, the data refers to main data (data payload; D0 to D7) and a strobe. The input/output path refers to the plurality of interconnects 108. The transmission circuit 107 converts the data into a signal and transmits the converted signal to an external chiplet via the plurality of interconnects 108. Here, the signal refers to a data signal and a differential signal. The differential signal includes a strobe signal and a clock signal. The data signal refers to a signal obtained by converting main data into an electrical signal. The differential signal may include a pair of complementary signals to suppress common-mode noise using the complementary signals. The strobe signal is a synchronization reference signal indicating when the reception unit 103 should sample data. The clock signal is a reference signal for synchronizing transmission and reception of data among a plurality of semiconductor chiplets. The data signals may be transmitted or received using a data lane or a repair lane. The differential signal may be transmitted or received using a strobe lane or a data lane. The strobe lanes and the data lanes may be arranged in parallel on an interposer.

The TX control unit 102 determines whether a defect has occurred in a plurality of interconnects connected to the transmission unit 101. When the TX control unit 102 determines that the defect has occurred in the plurality of interconnects connected to the transmission unit 101, the TX control unit 102 may apply a control signal to the TX single signal path selection unit 105 and the TX differential signal path selection unit 106 using the communication unit so that data is transferred using a redundancy TX/RX path. The TX single signal path selection unit 105 and the TX differential signal path selection unit 106, to which the control signal is applied, may select the redundancy TX/RX path. Here, the redundancy TX/RX path refers to a path that uses a repair lane. When the TX control unit 102 determines that no defect has occurred in the plurality of interconnects connected to the transmission unit 101, the TX control unit 102 may fix the redundancy TX/RX path to a specific voltage or deactivate the redundancy TX/RX path so that the redundancy TX/RX path is not used.

The reception unit 103 may include all or some of an RX differential signal path selection unit 109, an RX single signal path selection unit 111, an RX control unit 104, and a reception circuit 110. The reception unit 103 receives a data signal or a strobe signal of another chiplet.

Each of the RX single signal path selection unit 111 and the RX differential signal path selection unit 109 selects (maps) an electrical connection path between data transferred to a chiplet including a reception interface and the input/output path. The reception circuit 110 converts a signal into data, and receives a converted signal via the plurality of interconnects 108.

The RX control unit 104 determines whether a defect has occurred in a plurality of interconnects connected to the reception unit 103. When the RX control unit 104 determines that a defect has occurred in the plurality of interconnects connected to the reception unit 103, the RX control unit 104 may apply a control signal to the RX single signal path selection unit 111 and the RX differential signal path selection unit 109 using the communication unit so that data is transferred using the redundancy TX/RX path. The RX single signal path selection unit 111 and the RX differential signal path selection unit 109, to which the control signal is applied, may select the redundancy TX/RX path. When the RX control unit 104 determines that no defect has occurred in the plurality of interconnects connected to the reception unit 103, the RX control unit 104 may fix the redundancy TX/RX path to a specific voltage or deactivate the redundancy TX/RX path so that the redundancy TX/RX path is not used.

The plurality of interconnects 108 may include all or some of a plurality of data lanes, a plurality of strobe lanes, and a plurality of repair lanes. The plurality of interconnects 108 are disposed on the interposer. The interposer on which the plurality of interconnects 108 are disposed may further include a plurality of shield wirings.

When the TX control unit 102 determines that there is no defect in the interconnect, a path selection operation in the TX single signal path selection unit 105 and the TX differential signal path selection unit 106 is not performed, and the data signal and the strobe signal transmitted from the transmission unit 101 are transferred to the transmission circuit 107 using a fixed path. The transmission circuit 107 outputs each of the received data signal and strobe signal using the interconnect. Here, the path selection refers to the TX control unit 102 selecting a path through which the data signal and the strobe signal move.

When the RX control unit 104 determines that there is no defect in the interconnect, a path selection operation in the RX differential signal path selection unit 109 is not performed, and the data signal and the strobe signal of the reception unit 103 are transferred to the reception circuit 110. The data signal and the strobe signal received by the reception circuit 110 are output without path change in the RX single signal path selection unit 111.

When both the TX control unit 102 and the RX control unit 104 determine that there is no defect in the interconnect, the redundancy TX/RX path is not used, and thus may be fixed to a specific voltage or a TX/RX circuit may be deactivated. Since mapping of the redundancy TX/RX path requires synchronization between transmission and reception, both the TX control unit 102 and the RX control unit 104 should determine that there is no defect in the interconnect. The TX control unit 102 and the RX control unit 104 may communicate that there is no defect in the interconnect using the communication unit. Here, the redundancy TX/RX path refers to a path that uses a repair lane.

The shield wiring may be disposed on both sides of a plurality of strobe lanes to electromagnetically shield the strobe lanes. For example, the shield wiring may be a ground (GND) shield, a power (VDD) shield, a shield grid, or a floating shield. However, the present disclosure is not limited to these examples. The shield wiring may be designed to be disposed on both sides of the plurality of strobe lanes and on outer sides of some of a plurality of data lanes. The number of some of the plurality of data lanes disposed between the plurality of shield wirings may be set to correspond to the number of the plurality of strobe lanes.

According to an embodiment of the present disclosure, there may be provided a semiconductor package including a first chiplet including a transmission interface, a second chiplet including a reception interface, and a plurality of interconnects 108 that connect the first chiplet to the second chiplet. Here, an interposer on which the plurality of interconnects 108 are disposed may further include a plurality of shield wirings. Here, the plurality of interconnects 108 may include a plurality of data lanes, a plurality of strobe lanes, and a plurality of repair lanes. Here, the plurality of data lanes may transmit or receive at least one of a data signal and a differential signal, the plurality of strobe lanes may transmit or receive a differential signal, the plurality of repair lanes may transmit or receive a data signal, and the differential signal may include at least one of a strobe signal and a clock signal. Here, the interposer may be designed so that the plurality of shield wirings are disposed on both sides of the plurality of strobe lanes and on outer sides of some of the plurality of data lanes. The transmission interface of the semiconductor package according to an embodiment of the present disclosure may include the TX control unit 102 that determines whether a defect has occurred in the plurality of interconnects 108, and the reception interface may include the RX control unit 104 that determines whether a defect has occurred in the plurality of interconnects 108. In the semiconductor package according to an embodiment of the present disclosure, when at least one of the TX control unit 102 and the RX control unit 104 determines that a defect has occurred in the plurality of interconnects 108, at least one of the plurality of repair lanes may transmit or receive a data signal. Here, the defect occurring in the plurality of interconnects 108 refers to a defect occurring in at least one of the plurality of data lanes. In the semiconductor package according to the embodiment of the present disclosure, when at least one of the TX control unit 102 and the RX control unit 104 determines that a defect has occurred in the plurality of interconnects 108, at least one of the plurality of repair lanes may transmit or receive a data signal, and a data lane disposed between the plurality of shield wirings may transmit or receive a differential signal. Here, the defect occurring in the plurality of interconnects 108 refers to a defect occurring in at least one of the plurality of strobe lanes. In the semiconductor package according to the embodiment of the present disclosure, when at least one of the TX control unit 102 and the RX control unit 104 determines that a defect has occurred in the plurality of interconnects 108, at least one of the plurality of repair lanes may transmit or receive a data signal, and a data lane disposed between the plurality of shield wirings may transmit or receive a differential signal. Here, the defect occurring in the plurality of interconnects 108 refers to a defect occurring in at least one of each of the plurality of data lanes and the plurality of strobe lanes.

According to another embodiment of the present disclosure, there may be provided a chiplet including a transmission interface, which is connected to a reception interface of an external chiplet via a plurality of interconnects 108, and includes the plurality of interconnects 108. An interposer on which the plurality of interconnects are disposed may include a plurality of data lanes, a plurality of strobe lanes, and a plurality of repair lanes, Here, the interposer on which the plurality of interconnects are disposed may further include a plurality of shield wirings. The plurality of data lanes may transmit or receive at least one of a data signal and a differential signal, the plurality of strobe lanes may transmit or receive a differential signal, the plurality of repair lanes may transmit or receive a data signal, and the differential signal may include at least one of a strobe signal and a clock signal. The interposer may be designed so that the plurality of shield wirings are disposed on both sides of the plurality of strobe lanes and on outer sides of some of the plurality of data lanes. The transmission interface of the chiplet according to the other embodiment of the present disclosure may include the TX control unit 102 that determines whether a defect has occurred in the interconnect. In the chiplet according to the other embodiment of the present disclosure, when the TX control unit 102 determines that a defect has occurred in the plurality of interconnects 108, at least one of the plurality of repair lanes may transmit or receive a data signal. Here, the defect occurring in the plurality of interconnects 108 refers to a defect occurring in at least one of the plurality of data lanes. In the chiplet according to the other embodiment of the present disclosure, when the TX control unit 102 determines that a defect has occurred in the plurality of interconnects 108, at least one of the plurality of repair lanes may transmit or receive the data signal, and the data lane disposed between the plurality of shield wirings may transmit or receive the differential signal. Here, the defect occurring in the plurality of interconnects 108 refers to a defect occurring in at least one of the plurality of strobe lanes. According to the other embodiment of the present disclosure, when the TX control unit 102 determines that a defect has occurred in the plurality of interconnects 108, at least one of the plurality of repair lanes may transmit or receive the data signal, and the data lane disposed between the plurality of shield wirings may transmit or receive the differential signal. Here, the defect occurring in the plurality of interconnects 108 refers to a defect occurring in at least one of each of the plurality of data lanes and the plurality of strobe lanes.

According to still another embodiment of the present disclosure, there may be provided a chiplet including a reception interface, which is connected to a transmission interface of an external chiplet via a plurality of interconnects 108, wherein the plurality of interconnects 108 may include a plurality of data lanes, a plurality of strobe lanes, and a plurality of repair lanes. Here, an interposer on which the plurality of interconnects 108 are disposed may further include a plurality of shield wirings. Here, the plurality of data lanes may transmit or receive at least one of a data signal and a differential signal, the plurality of strobe lanes may transmit or receive a differential signal, the plurality of repair lanes may transmit or receive a data signal, and the differential signal may include at least one of a strobe signal and a clock signal. The interposer may be designed so that the plurality of shield wirings are disposed on both sides of the plurality of strobe lanes and on outer sides of some of the plurality of data lanes. The reception interface of the chiplet according to still another embodiment of the present disclosure may include an RX control unit 104 that determines whether a defect has occurred in the plurality of interconnects 108. In the chiplet according to still another embodiment of the present disclosure, when the RX control unit 104 determines that a defect has occurred in the plurality of interconnects 108, at least one of the plurality of repair lanes may transmit or receive the data signal. Here, the defect occurring in the plurality of interconnects 108 refers to a defect occurring in at least one of the plurality of data lanes. In the chiplet according to still another embodiment of the present disclosure, when the RX control unit 104 determines that a defect has occurred in the plurality of interconnects 108, at least one of the plurality of repair lanes may transmit or receive the data signal, and the data lane disposed between the plurality of shield wirings may transmit or receive the differential signal. Here, the defect occurring in the plurality of interconnects 108 refers to a defect occurring in at least one of the plurality of strobe lanes. In the chiplet according to still another embodiment of the present disclosure, when the RX control unit 104 determines that a defect has occurred in the plurality of interconnects 108, at least one of the plurality of repair lanes may transmit or receive a data signal, and the data lane disposed between the plurality of shield wirings may transmit or receive the differential signal. Here, the defect occurring in the plurality of interconnects 108 refers to a defect occurring in at least one of each of the plurality of data lanes and the plurality of strobe lanes.

According to still another embodiment of the present disclosure, there may be provided a chiplet including a transmission interface that transmits signals using a first plurality of interconnects; and a reception interface that receives signals using a second plurality of interconnects. Here, each of the first plurality of interconnects and the second plurality of interconnects may include a data lane, a strobe lane, and a repair lane. Here, each interposer on which the first plurality of interconnects and the second plurality of interconnects are disposed may further include shield wirings. Here, each shield wiring may include a plurality of shield wirings. Here, each data lane may include a plurality of data lanes to transmit or receive at least one of the data signal and the differential signal, each strobe lane may include a plurality of strobe lanes to transmit or receive a differential signal, each repair lane may include a plurality of repair lanes to transmit or receive a data signal, and the differential signal may include at least one of a strobe signal and a clock signal. The interposer may be designed so that the shield wiring is disposed on both sides of the strobe lanes and on an outer side of some of the data lanes. The transmission interface of the chiplet according to still another embodiment of the present disclosure may include the TX control unit 102 that determines whether a defect has occurred in the first plurality of interconnects. The reception interface of the chiplet according to still another embodiment of the present disclosure may include the RX control unit 104 that determines whether a defect has occurred in the second plurality of interconnects. Here, when the TX control unit 102 determines that a defect has occurred in the first plurality of interconnects or when the RX control unit 104 determines that a defect has occurred in the second plurality of interconnects, at least one of the repair lanes disposed in the interconnect in which the defect has occurred may transmit or receive a data signal. Here, the defect occurring in at least one of the first plurality of interconnects and the second plurality of interconnects refers to a defect occurring in at least one of the data lanes. In the chiplet according to still another embodiment of the present disclosure, when the TX control unit 102 determines that a defect has occurred in the first plurality of interconnects or when the RX control unit 104 determines that a defect has occurred in the second plurality of interconnects, at least one of the repair lanes disposed in the interconnect in which the defect has occurred may transmit or receive a data signal, and a data lane disposed in the interconnect in which the defect has occurred and disposed between the plurality of shield wirings may transmit or receive a differential signal. Here, the defect occurring in at least one of the first plurality of interconnects and the second plurality of interconnects refers to a defect occurring in at least one of the strobe lanes. In the chiplet according to still another embodiment of the present disclosure, when the TX control unit 102 determines that a defect has occurred in the first plurality of interconnects or when the RX control unit 104 determines that a defect has occurred in the second plurality of interconnects, at least one of the repair lanes disposed in the interconnect in which the defect has occurred may transmit or receive a data signal, and a data lane disposed in the interconnect in which the defect has occurred and disposed between the plurality of shield wirings may transmit or receive the differential signal. Here, the defect occurring in at least one of the first plurality of interconnects and the second plurality of interconnects refers to a defect occurring in at least one of each of the data lanes and the strobe lanes.

When at least one of the RX control unit 104 and the TX control unit 102 determines that a defect has occurred in the strobe lane, the repair lane may not be used as a redundancy path for the strobe lane. Here, a data lane shielded by the shield wiring may be used as the redundancy path for the strobe lane to transmit or receive a differential signal. The use of the data lane shielded by the shield wiring to transmit or receive the differential signal is intended to maintain characteristics of the differential signal. The differential signal has a structure in which two signal lines operate in opposite phases to cancel external radiation noise. As external electromagnetic interference (EMI) becomes stronger, an entire differential pair is subjected to interference in the same manner, thereby generating common-mode noise, and the generated common-mode noise is difficult to ideally cancel. Accordingly, the differential signal can maintain signal quality by reducing inflow of an external electromagnetic field using the shielded lane. The differential signal can reduce crosstalk between adjacent signal lines using the shielded lane. The differential signal can reduce reflection and loss by reducing variation in differential impedance using the shielded lane. The differential signal can suppress resonance or prevent radiation from leaking to the outside using the shielded lane. That is, the differential signal can ensure signal integrity (SI) by reducing external interference and internal crosstalk and stabilizing impedance, by using a strobe lane shielded by the shield wiring. When a defect occurs in the strobe lane, the differential signal may be transmitted or received using a data lane shielded by the shield wiring to maintain characteristics of the differential signal, similarly to the strobe lane shielded by the shield wiring.

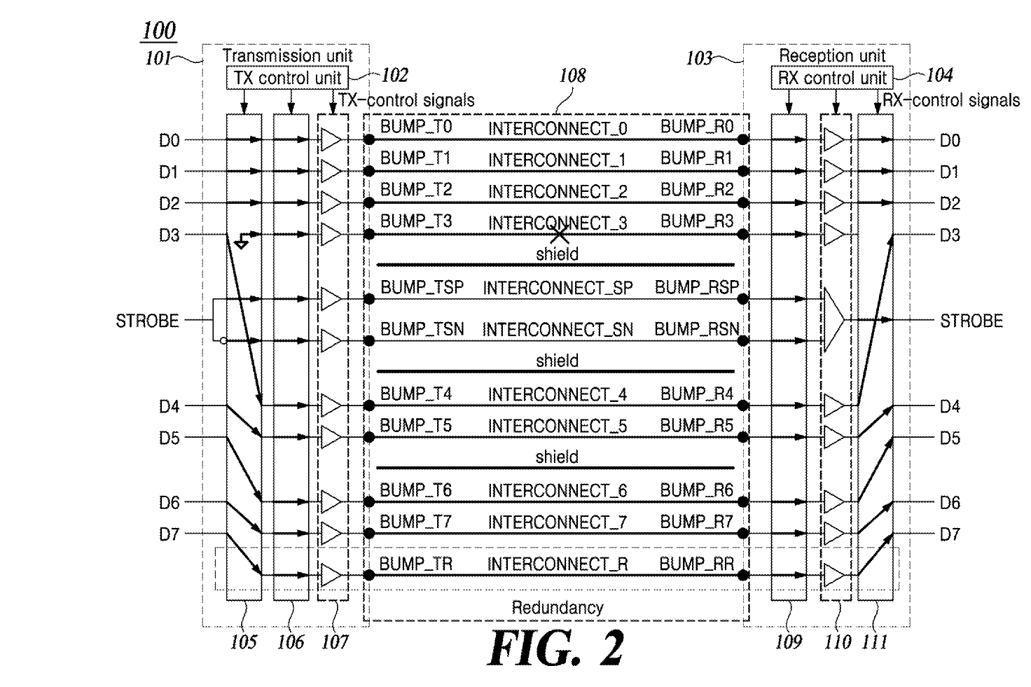

FIG. 2 is a diagram illustrating an operation of an input/output interface including a repair lane when the interconnect of the data lane has a defect according to an embodiment of the present disclosure.

FIG. 2 illustrates a case in which a defect occurs in an interconnect of INTERCONNECT_3, which is one of the data lanes, in the input/output interface 100 including a repair lane of FIG. 1.

When at least one of the TX control unit 102 and the RX control unit 104 determines that a defect has occurred in the interconnect, the TX control unit 102 controls the TX single signal path selection unit 105 so that the TX single signal path selection unit 105 uses a transmission circuit using BUMP_T3. The TX control unit 102 controls the TX single signal path selection unit 105 so that the path of the data signal is changed. The TX single signal path selection unit 105 selects a path of the data signal so that INTERCONNECT_R is used instead of INTERCONNECT_3. A node voltage of a transmission circuit and a reception circuit connected to INTERCONNECT_3 may be fixed to a specific voltage, or the transmission circuit and the reception circuit connected to INTERCONNECT_3 may be deactivated. The RX control unit 104 controls the RX single signal path selection unit 111 so that the data signal is output using a path of INTERCONNECT_3 when there is no defect in the interconnect.

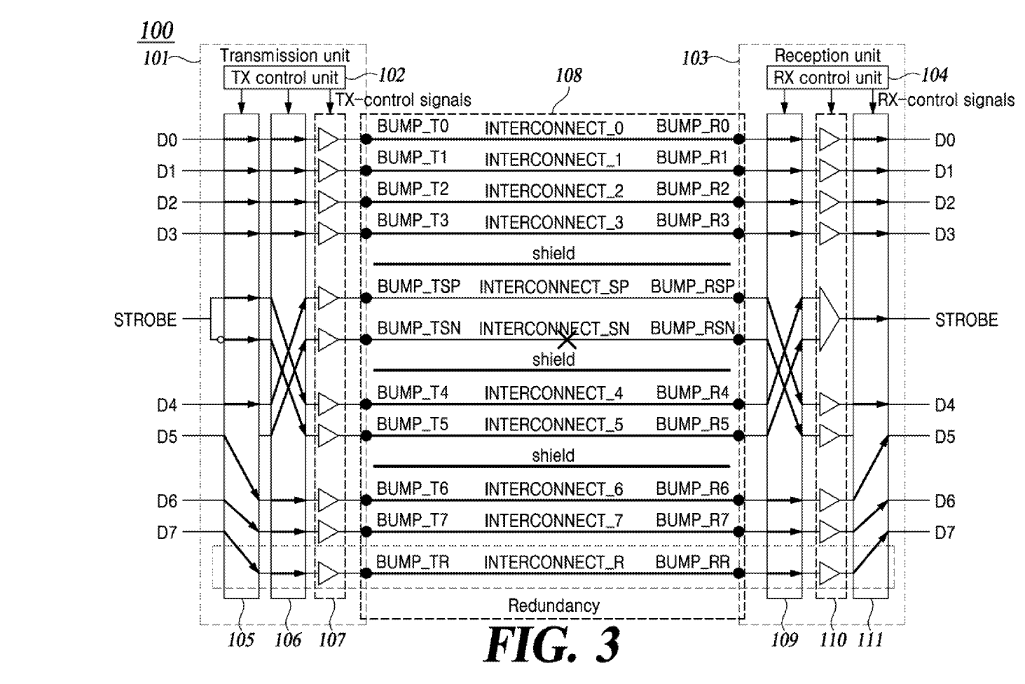

FIG. 3 is a diagram illustrating an operation of an input/output interface including a repair lane when the interconnect of the strobe lane has a defect, according to an embodiment of the present disclosure.

FIG. 3 illustrates a case in which a defect occurs in an interconnect of INTERCONNECT_SN, which is one of the strobe lanes, in the input/output interface 100 including a repair lane of FIG. 1.

When at least one of the TX control unit 102 and the RX control unit 104 determines that a defect has occurred in the interconnect, the TX control unit 102 controls the TX single signal path selection unit 105 so that the TX single signal path selection unit 105 changes data signal paths D5 to D7. The TX differential signal path selection unit 106 selects paths for the data signal and the strobe signal so that INTERCONNECT_SN is not used. A node voltage of a transmission circuit and a reception circuit connected to INTERCONNECT_SN may be fixed to a specific voltage, or the transmission circuit and the reception circuit connected to INTERCONNECT_SN may be deactivated. The RX control unit 104 controls the RX differential signal path selection unit 109 and the RX single signal path selection unit 111 so that the data signals and the strobe signal are output using a path of INTERCONNECT_SN when there is no defect in the interconnect.

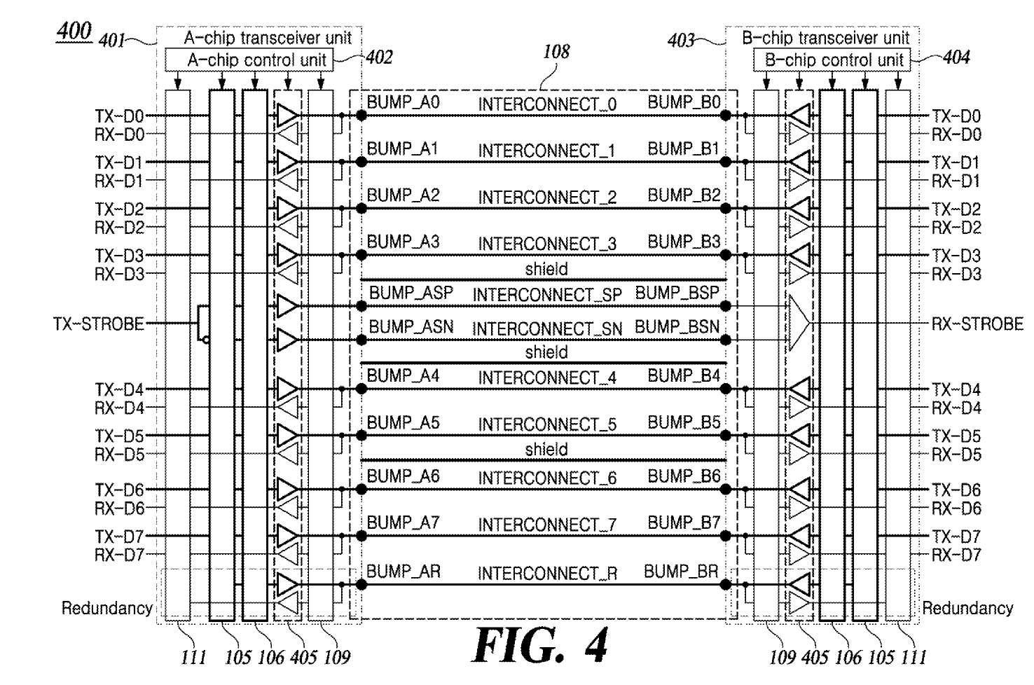

FIG. 4 is a diagram illustrating a transceiver interface including a repair lane according to an embodiment of the present disclosure.

In a transceiver, a function of a transmitter and a function of a receiver are integrated into one circuit or device.

A transceiver interface 400 including a repair lane may include all or some of an A-chip transceiver unit 401, a B-chip transceiver unit 403, a plurality of interconnects 406, and a communication unit (not shown). Not all components illustrated in FIG. 4 are essential components, and some components may be modified or omitted, or other components may be added.

Respective components of the transceiver interface 400 including a repair lane may exchange signals with each other using the communication unit. The signals may include data. For example, the signals may be electrical signals or optical signals, but are not limited to these examples.

The A-chip transceiver unit 401 may include all or some of the TX single signal path selection unit 105, the TX differential signal path selection unit 106, the RX differential signal path selection unit 109, the RX single signal path selection unit 111, an A-chip control unit 402, and a transceiver circuit 405. The A-chip transceiver unit 401 transmits or receives its own data signal or strobe signal to or from another chiplet.

The A-chip control unit 402 determines whether a defect has occurred in an interconnect connected to the A-chip transceiver unit 401. When the A-chip control unit 402 determines that a defect has occurred in the interconnect connected to the A-chip transceiver unit 401, the A-chip control unit 402 may apply control signals to the TX single signal path selection unit 105 and the TX differential signal path selection unit 106 using the communication unit. The TX single signal path selection unit 105 and the TX differential signal path selection unit 106, to which the control signals are applied, may select a redundancy TX/RX path so that data is transferred using the redundancy TX/RX path. When the A-chip control unit 402 determines that a defect has occurred in the interconnect connected to the A-chip transceiver unit 401, the A-chip control unit 402 may apply control signals to the RX single signal path selection unit 111 and the RX differential signal path selection unit 109 using the communication unit. The RX single signal path selection unit 111 and the RX differential signal path selection unit 109, to which the control signals are applied, may select the redundancy TX/RX path so that data is transferred using the redundancy TX/RX path. When the A-chip control unit 402 determines that no defect has occurred in the interconnect connected to the A-chip transceiver unit 401, the A-chip control unit 402 may fix the redundancy TX/RX path to a specific voltage or deactivate the redundancy TX/RX path so that the redundancy TX/RX path is not used.

The B-chip transceiver unit 403 may include all or some of the TX single signal path selection unit 105, the TX differential signal path selection unit 106, the RX differential signal path selection unit 109, the RX single signal path selection unit 111, a B-chip control unit 404, and the transceiver circuit 405. The B-chip transceiver unit 403 transmits or receives a data signal or a strobe signal to or from another chiplet.

The B-chip control unit 404 determines whether a defect has occurred in an interconnect connected to the B-chip transceiver unit 403. When the B-chip control unit 404 determines that a defect has occurred in the interconnect connected to the B-chip transceiver unit 403, the B-chip control unit 404 may apply control signals to the TX single signal path selection unit 105 and the TX differential signal path selection unit 106 using the communication unit. The TX single signal path selection unit 105 and the TX differential signal path selection unit 106, to which the control signals are applied, may select the redundancy TX/RX path so that data is transferred using the redundancy TX/RX path. When the B-chip control unit 404 determines that a defect has occurred in the interconnect connected to the B-chip transceiver unit 403, the B-chip control unit 404 may apply control signals to the RX single signal path selection unit 111 and the RX differential signal path selection unit 109 using the communication unit. The RX single signal path selection unit 111 and the RX differential signal path selection unit 109, to which the control signals are applied, may select the redundancy TX/RX path so that data is transferred using the redundancy TX/RX path. When the B-chip control unit 404 determines that no defect has occurred in the interconnect connected to the B-chip transceiver unit 403, the B-chip control unit 404 may fix the redundancy TX/RX path to a specific voltage or deactivate the redundancy TX/RX path so that the redundancy TX/RX path is not used.

The interconnects 406 may include all or some of a plurality of data lanes, a plurality of strobe lanes, and a plurality of repair lanes. The interconnects 406 are disposed on the interposer.

When the A-chip transceiver unit 401 of the transceiver interface 400 including a repair lane transmits a signal, the B-chip transceiver unit 403 of the transceiver interface 400 including a repair lane receives the signal. When the B-chip transceiver unit 403 of the transceiver interface 400 including a repair lane transmits a signal, the A-chip transceiver unit 401 of the transceiver interface 400 including a repair lane receives the signal.

The components described in the example embodiments may be implemented by hardware components including, for example, at least one digital signal processor (DSP), a processor, a controller, an application-specific integrated circuit (ASIC), a programmable logic element, such as an FPGA, other electronic devices, or combinations thereof.

At least some of the functions or the processes described in the example embodiments may be implemented by software, and the software may be recorded on a recording medium. The components, the functions, and the processes described in the example embodiments may be implemented by a combination of hardware and software.

The method according to example embodiments may be embodied as a program that is executable by a computer, and may be implemented as various recording media such as a magnetic storage medium, an optical reading medium, and a digital storage medium.

Various techniques described herein may be implemented as digital electronic circuitry, or as computer hardware, firmware, software, or combinations thereof. The techniques may be implemented as a computer program product, i.e., a computer program tangibly embodied in an information carrier, e.g., in a machine-readable storage device (for example, a computer-readable medium) or in a propagated signal for processing by, or to control an operation of a data processing apparatus, e.g., a programmable processor, a computer, or multiple computers. A computer program(s) may be written in any form of a programming language, including compiled or interpreted languages and may be deployed in any form including a stand-alone program or a module, a component, a subroutine, or other units suitable for use in a computing environment. A computer program may be deployed to be executed on one computer or on multiple computers at one site or distributed across multiple sites and interconnected by a communication network.

Processors suitable for execution of a computer program include, by way of example, both general and special purpose microprocessors, and any one or more processors of any kind of digital computer. Generally, a processor will receive instructions and data from a read-only memory or a random access memory or both. Elements of a computer may include at least one processor to execute instructions and one or more memory devices to store instructions and data. Generally, a computer will also include or be coupled to receive data from, transfer data to, or perform both on one or more mass storage devices to store data, e.g., magnetic, magneto-optical disks, or optical disks. Examples of information carriers suitable for embodying computer program instructions and data include semiconductor memory devices, for example, magnetic media such as a hard disk, a floppy disk, and a magnetic tape, optical media such as a compact disk read only memory (CD-ROM), a digital video disk (DVD), etc. and magneto-optical media such as a floptical disk, and a read only memory (ROM), a random access memory (RAM), a flash memory, an erasable programmable ROM (EPROM), and an electrically erasable programmable ROM (EEPROM) and any other known computer readable medium. A processor and a memory may be supplemented by, or integrated into, a special purpose logic circuit.

The processor may run an operating system (OS) and one or more software applications that run on the OS. The processor device also may access, store, manipulate, process, and create data in response to execution of the software. For purpose of simplicity, the description of a processor device is used as singular; however, one skilled in the art will be appreciated that a processor device may include multiple processing elements and/or multiple types of processing elements. For example, a processor device may include multiple processors or a processor and a controller. In addition, different processing configurations are possible, such as parallel processors.

Also, non-transitory computer-readable media may be any available media that may be accessed by a computer, and may include both computer storage media and transmission media.

The present specification includes details of a number of specific implements, but it should be understood that the details do not limit any invention or what is claimable in the specification but rather describe features of the specific example embodiment. Features described in the specification in the context of individual example embodiments may be implemented as a combination in a single example embodiment. In contrast, various features described in the specification in the context of a single example embodiment may be implemented in multiple example embodiments individually or in an appropriate sub-combination. Furthermore, the features may operate in a specific combination and may be initially described as claimed in the combination, but one or more features may be excluded from the claimed combination in some cases, and the claimed combination may be changed into a sub-combination or a modification of a sub-combination.

Similarly, even though operations are described in a specific order on the drawings, it should not be understood as the operations needing to be performed in the specific order or in sequence to obtain desired results or as all the operations needing to be performed. In a specific case, multitasking and parallel processing may be advantageous. In addition, it should not be understood as requiring a separation of various apparatus components in the above described example embodiments in all example embodiments, and it should be understood that the above-described program components and apparatuses may be incorporated into a single software product or may be packaged in multiple software products.

As described above, according to an embodiment of the present disclosure, a cloud-based system for cultivating roughage may enable a grower to cultivate roughage conveniently by remotely controlling a cultivation apparatus.

According to an embodiment of the present disclosure, the cloud-based system for cultivating roughage may enable a grower to control a cultivation apparatus in a cost-effective manner.

The effects of embodiments of the present disclosure are not limited to the above-mentioned effects, and other effects not mentioned will be clearly understood by those skilled in the art from the above description.

It should be understood that the example embodiments disclosed herein are merely illustrative and are not intended to limit the scope of the invention. It will be apparent to one of ordinary skill in the art that various modifications of the example embodiments may be made without departing from the spirit and scope of the claims and their equivalents.

Accordingly, one of ordinary skill would understand that the scope of the claimed invention is not to be limited by the above explicitly described embodiments but by the claims and equivalents thereof.

What is claimed is:

1. A semiconductor package comprising:
a first chiplet including a transmission interface;
a second chiplet including a reception interface; and
a plurality of interconnects configured to connect the first chiplet to the second chiplet,
wherein an interposer on which the plurality of interconnects are disposed further includes a plurality of shield wirings,
the plurality of interconnects include a plurality of data lanes, a plurality of strobe lanes, and a plurality of repair lanes,
the plurality of data lanes transmit or receive at least one of a data signal and a differential signal, the plurality of strobe lanes transmit or receive a differential signal, and the plurality of repair lanes transmit or receive a data signal, and
the differential signal includes at least one of a strobe signal and a clock signal.

2. The semiconductor package of claim 1,
wherein the interposer is designed so that the plurality of shield wirings are disposed on both sides of the plurality of strobe lanes and on outer sides of some of the plurality of data lanes,
the transmission interface includes a TX control unit configured to determine whether a defect has occurred in the plurality of interconnects, and
the reception interface includes an RX control unit configured to determine whether a defect has occurred in the plurality of interconnects.

3. The semiconductor package of claim 2,
wherein, when at least one of the TX control unit and the RX control unit determines that a defect has occurred in the plurality of interconnects, at least one of the plurality of repair lanes transmits or receives a data signal, and
the defect occurring in the plurality of interconnects is a defect occurring in at least one of the plurality of data lanes.

4. The semiconductor package of claim 2,
wherein, when at least one of the TX control unit and the RX control unit determines that a defect has occurred in the plurality of interconnects, at least one of the plurality of repair lanes transmits or receives a data signal, and the data lane disposed between the plurality of shield wirings transmits or receives a differential signal, and
the defect occurring in the plurality of interconnects is a defect occurring in at least one of the plurality of strobe lanes.

5. The semiconductor package of claim 2,
wherein, when at least one of the TX control unit and the RX control unit determines that a defect has occurred in the plurality of interconnects, at least one of the plurality of repair lanes transmits or receives a data signal, and the data lane disposed between the plurality of shield wirings transmits or receives a differential signal, and
the defect occurring in the plurality of interconnects is a defect occurring in at least one of each of the plurality of data lanes and the plurality of strobe lanes.

6. A chiplet including a transmission interface,
wherein the chiplet is connected to a reception interface unit of an external chiplet via a plurality of interconnects,
the plurality of interconnects include a plurality of data lanes, a plurality of strobe lanes, and a plurality of repair lanes,
an interposer on which the plurality of interconnects are disposed further includes a plurality of shield wirings,
the plurality of data lanes transmit or receive at least one of a data signal and a differential signal,
the plurality of strobe lanes transmit or receive a differential signal,
the plurality of repair lanes transmit or receive a data signal, and
the differential signal includes at least one of a strobe signal and a clock signal.

7. The chiplet of claim 6,
wherein the interposer is designed so that the plurality of shield wirings are disposed on both sides of the plurality of strobe lanes and on outer sides of some of the plurality of data lanes, and
the transmission interface includes a TX control unit configured to determine whether a defect has occurred in the interconnects.

8. The chiplet of claim 7,
wherein, when the TX control unit determines that a defect has occurred in the plurality of interconnects, at least one of the plurality of repair lanes transmits or receives a data signal, and
the defect occurring in the plurality of interconnects is a defect occurring in at least one of the plurality of data lanes.

9. The chiplet of claim 7,
wherein, when the TX control unit determines that a defect has occurred in the plurality of interconnects, at least one of the plurality of repair lanes transmits or receives a data signal, and the data lane disposed between the plurality of shield wirings transmits or receives a differential signal, and
the defect occurring in the plurality of interconnects is a defect occurring in at least one of the plurality of strobe lanes.

10. The chiplet of claim 7,
wherein, when the TX control unit determines that a defect has occurred in the plurality of interconnects, at least one of the plurality of repair lanes transmits or receives a data signal, and the data lane disposed between the plurality of shield wirings transmits or receives a differential signal, and
the defect occurring in the plurality of interconnects is a defect occurring in at least one of each of the plurality of data lanes and the plurality of strobe lanes.

11. A chiplet including a reception interface,
wherein the chiplet is connected to a transmission interface unit of an external chiplet via a plurality of interconnects,
the plurality of interconnects include a plurality of data lanes, a plurality of strobe lanes, and a plurality of repair lanes,
an interposer on which the plurality of interconnects are disposed further includes a plurality of shield wirings,
the plurality of data lanes transmit or receive at least one of a data signal and a differential signal, the plurality of strobe lanes transmit or receive a differential signal, and the plurality of repair lanes transmit or receive a data signal, and
the differential signal includes at least one of a strobe signal and a clock signal.

12. The chiplet of claim 11,
wherein the interposer is designed so that the plurality of shield wirings are disposed on both sides of the plurality of strobe lanes and on outer sides of some of the plurality of data lanes, and
the reception interface includes an RX control unit configured to determine whether a defect has occurred in the plurality of interconnects.

13. The chiplet of claim 12,
wherein, when the RX control unit determines that a defect has occurred in the plurality of interconnects, at least one of the plurality of repair lanes transmits or receives a data signal, and
the defect occurring in the interconnects is a defect occurring in at least one of the plurality of data lanes.

14. The chiplet of claim 12,
wherein, when the RX control unit determines that a defect has occurred in the plurality of interconnects, at least one of the plurality of repair lanes transmits or receives a data signal, and the data lane disposed between the plurality of shield wirings transmits or receives a differential signal, and
the defect occurring in the plurality of interconnects is a defect occurring in at least one of the plurality of strobe lanes.

15. The chiplet of claim 12,
wherein, when the RX control unit determines that a defect has occurred in the plurality of interconnects, at least one of the plurality of repair lanes transmits or receives a data signal, and the data lane disposed between the plurality of shield wirings transmits or receives a differential signal, and
the defect occurring in the plurality of interconnects is a defect occurring in at least one of each of the plurality of data lanes and the plurality of strobe lanes.
